(19) United States
(12) Patent Application Publication
(10) Pub. No.: US 2020/0111469 A1
(43) Pub. Date: Apr. 9, 2020

(54) FUNDAMENTAL FREQUENCY DETECTION USING PEAK DETECTORS WITH FREQUENCY-CONTROLLED DECAY TIME

(71) Applicant: Second Sound, LLC, Miami, FL (US)

(72) Inventor: Brian Kaczynski, Krakow (PL)

(73) Assignee: Second Sound, LLC, Miami, FL (US)

(21) Appl. No.: 16/154,837

(22) Filed: Oct. 9, 2018

(51) Int. Cl. G10H 5/00; H03L 7/099; H03L 7/091; G10H 5/04

(52) U.S. Cl. CPC G10H 5/002; G10H 5/04; H03L 7/091; H03L 7/0992

(57) ABSTRACT

Methods and digital circuits providing frequency correction to frequency synthesizers are disclosed. Dual switched-capacitor peak detectors connected to an input signal periodically sample the voltage of the input signal, and then determine a fundamental frequency of the input signal from the output of the dual switched-capacitor peak detectors. Both the sample period and the decay time of the dual switched-capacitor peak detectors are proportional to a time period between a previous pair of voltage peaks detected in the input signal. This makes the peak detectors immune to lower-amplitude oscillations which are often present within a single fundamental cycle in musical signals with strong harmonic components which might otherwise cause errors in frequency estimation. This is done without causing unwanted sluggishness in the transient response of the frequency detection process. The time period between the previous pair of detected voltage peaks is used to create a decay signal that initiates a capacitor decay time for each peak detector.

### BACKGROUND

This disclosure is directed to a method of detecting of an audio signal fundamental frequency without filtering the input signal in order to achieve a minimum possible physically achievable latency of one audio cycle.

The fast-locking frequency synthesizer presented in U.S. Pat. No. 9,685,964 works well for musical signals which don't possess strong harmonic components. With the addition of the disclosure described in U.S. Pat. No. 9,824,673 (a CIP filing based on the previously-mentioned U.S. Pat. No. 9,685,964), it is possible to filter harmonics of the fundamental and improve frequency tracking for more complex musical signals. However, the transient response of the filter described in U.S. Pat. No. 9,824,673 causes audible latency, especially for bass instruments in the 20-80 Hz range. A method of detecting fundamental frequency without filtering the input signal is desired in order to achieve the minimum possible physically achievable latency of one audio cycle.

### SUMMARY

In order to mitigate synthesizer locking to harmonics of a fundamental frequency of an input signal, a new method is proposed which uses dual switched-capacitor peak detectors connected to the input signal to periodically sample the voltage of the input signal. Both the sample period and a decay time of the dual switched-capacitor peak detectors are proportional to a time period between a previous pair of voltage peaks detected in the input signal. This makes the peak detectors immune to lower-amplitude oscillations which are often present within a single fundamental cycle in musical signals with strong harmonic components which might otherwise cause errors in frequency estimation. This is done without causing unwanted sluggishness in the transient response of the frequency detection process.

Implementations are disclosed herein of dual peak detectors with frequency-controlled decay time that isolate the fundamental frequency in a music signal to avoid false zero crossings and the errors in frequency tracking caused as a result.

These implementations are mentioned not to limit or define the scope of the disclosure, but to provide an example of an implementation of the disclosure to aid in understanding thereof. Particular implementations may be developed to realize one or more of the following advantages.

### BRIEF DESCRIPTION OF THE DRAWINGS

The details of one or more implementations are set forth in the accompanying drawings and the description below. Other features, aspects, and advantages of the disclosure will become apparent from the description, the drawings, and the claims, in which:

FIG. 1 is a block diagram of the frequency-locked loop system described in U.S. Pat. No. 9,685,964, where the Reference Frequency 102 will be generated by the disclosure described herein and the output of the Digitally-Controlled Oscillator (DCO) 110 is called CKDCO.

FIG. 2 is a block diagram of the fundamental frequency detection circuit consisting of two peak detectors, one of which has an inverting amplifier in front of it, and logic gates implementing an SR latch, where signal CKREF 210 serves as the Reference Frequency 102 input in the larger system.

FIG. 3 is one embodiment of a switched-capacitor peak detector with decay time proportional to the detected fundamental frequency.

FIG. 4a is a simplified schematic diagram of the switched-capacitor peak detector phase generator 350.

FIG. 4b is a continuation of the schematic diagram of the switched-capacitor peak detector phase generator in which the generation of phases ϕ4, ϕ5, ϕ6, and ϕ7 is illustrated.

FIG. 5 is a graph of an audio signal with strong harmonic components (in this case, from a violin playing the lowest open string, a G3, with a fundamental frequency of 196 Hz) together with the outputs of the positive peak detector (ppeak) and negative peak detector (npeak) in three different rate modes (rate=0, 1, and 2).

FIG. 6 is a schematic of a zero-ripple envelope detector consisting of a sample-and-hold amplifier with sample and hold phases selected to give an output representing a zero ripple envelope signal based on the audio input.

Like reference numbers and designations in the various drawings indicate like elements.

### DETAILED DESCRIPTION

Numerous specific details may be set forth below to provide a thorough understanding of concepts underlying the described implementations. It may be apparent, however, to one skilled in the art that the described implementations may be practiced without some or all of these specific details. In other instances, some process steps have not been described in detail in order to avoid unnecessarily obscuring the underlying concept.

In any synthesizer which tracks the fundamental input frequency of a musical signal, from a voice or any instrument, including but not limited to electric guitar, bass guitar, brass, woodwinds, bowed strings, percussion, it is of crucial important to correctly identify the fundamental frequency in that signal. Often the second, third, or higher harmonics are larger in amplitude than the fundamental and create spurious zero crossings which persist even after low-pass filtering, which make detection based on filtering and detecting zero crossings problematic. Because the “musically useful” frequency range of all instruments covers about 8 octaves, a method is desired whose transient behavior properly scales with the input frequency. Adaptive filters such as the one described in U.S. Pat. No. 9,824,673 are also problematic as they noticeably slow down the transient response of the fundamental frequency detection, especially for signals in the bass range (20-100 Hz).

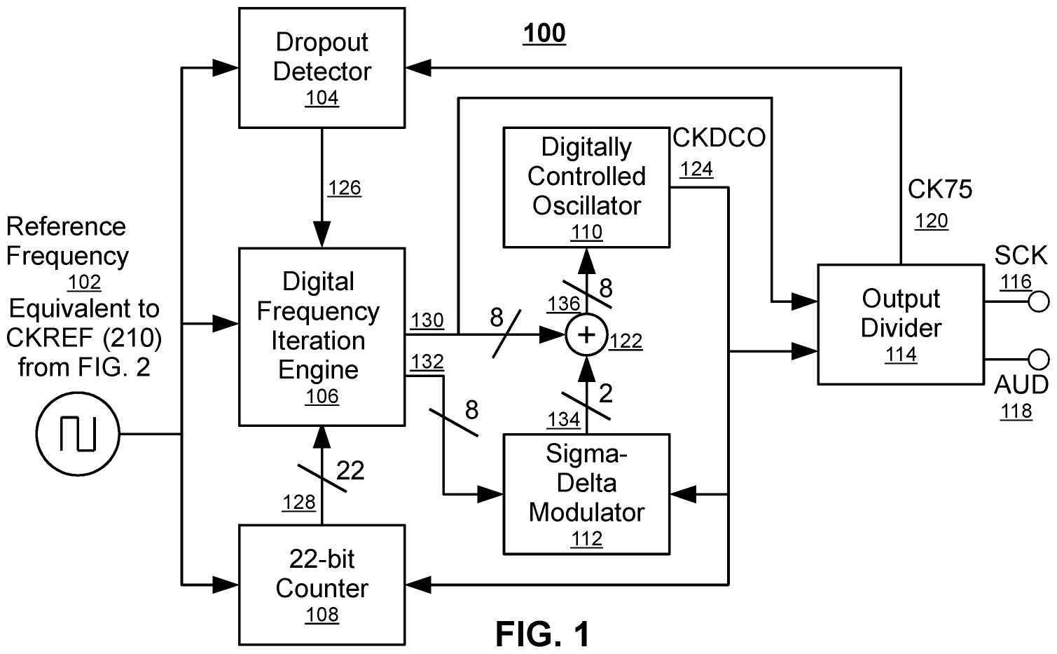

The fast-locking frequency synthesizer (“FLL”) described in U.S. Pat. No. 9,685,964, which is incorporated herein by reference in its entirety, is illustrated in FIG. 1. The present disclosure concerns the generation of the Reference Frequency signal 102, illustrated in FIG. 1 as one cycle of a square wave. In practice musical signals are much more complex than a square wave and require special care for detecting their fundamental frequency. The FLL is a frequency-locked loop circuit comprising a digitally controlled oscillator 110 configured to generate a first frequency; and a digital frequency iteration engine 106. The digital frequency iteration engine 106 comprises a first circuit configured to receive the first frequency and a reference frequency and generate a number of first frequency cycles in one reference frequency cycle. The digital frequency iteration engine 106 also includes a second circuit configured to receive the number of first frequency cycles and generate a second frequency based on a predetermined frequency multiplication factor. The determined number of first frequency cycles, the first frequency, and the reference frequency, provides a predetermined frequency multiplication factor that provides a target relationship between the first frequency and the reference frequency.

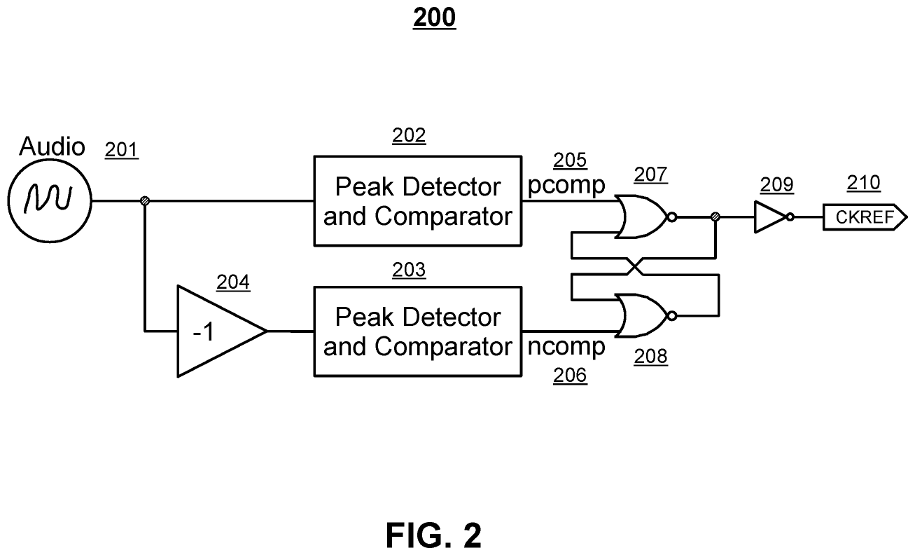

The present disclosure is illustrated in FIG. 2. It consists of two peak detectors and comparators, one driven by an audio input signal 201 and another driven by an inverted version of this audio signal produced with an inverting amplifier (or virtual inversion using a differential signaling) 204. In practice, the circuits shown here and in subsequent figures can be implemented as differential rather than single-ended circuits, although the single-ended versions of these circuits are shown in the figures for simplicity. With differential circuits, no amplifier is needed for an inversion, which can be achieved simply by swapping the positive and negative polarity signals.

The two peak detectors 202 and 203 are connected to the input signal 201 to periodically sample the voltage of the input signal 201 to create two comparator outputs, pcomp and ncomp (205 and 206). These comparator outputs are followed by an SR latch composed of cross-coupled NOR gates 207 and 208, with NOR gate 207 followed by inverter 209 to generate the reference clock signal CKREF 210 of the correct polarity. Note that if the polarity of the comparator outputs is reversed, the NOR gates can be replaced by NAND gates with no difference in functionality. The details of how this circuit functions as a fundamental frequency detector are hidden in the inner workings of the peak detector and comparator, which will be described next.

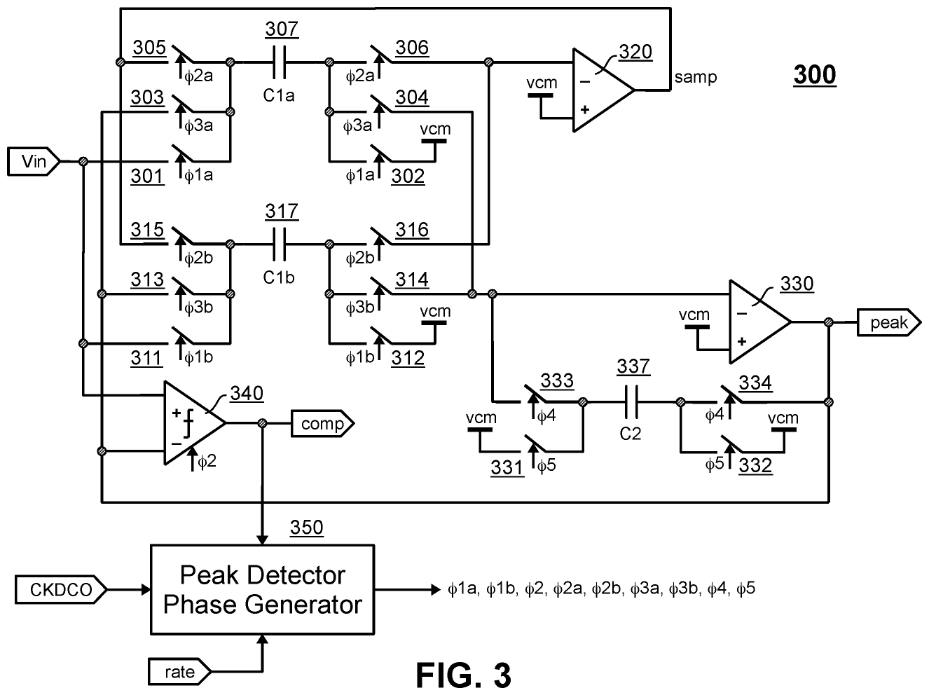

FIG. 3 shows the details of the peak detector and comparator implementation. The peak detector consists of two identical switched capacitor networks, each containing one capacitor C1a/C1b (or pair of capacitors in the case of differential signaling) and 6 switches for each capacitor, two op amps, a third switched capacitor network containing a different capacitor C2 and four switches, a comparator, and a digital phase generator circuit. As stated earlier, for simplicity the single-ended version of this circuit is shown in the figures and described herein, although in practice a differential version may be preferable for performance reasons.

Op amp 320 serves as a sample-and-hold amplifier (with output samp) and op amp 330 serves as a peak hold amplifier (with output peak). The CKDCO signal which serves as the input to peak detector phase generator 350 is the same as signal 124 in FIG. 1, the output of the digitally controlled oscillator 110. In the implementation described in U.S. Pat. No. 9,685,964, this digitally controlled oscillator generates a square wave whose frequency is 8,192 times the frequency presented at the input as the reference frequency 102. This CKDCO serves as the sample clock for the switched capacitor circuits described herein. In particular, the sample-and-hold circuit samples the audio input at 8,192 times the detected fundamental frequency. This ensures that even when the FLL is not yet locked to the fundamental of the audio, the system is still sampling the audio with high enough resolution to avoid even the remotest possibility of aliasing.

The working of the peak detector can be understood as follows. Each of two capacitors C1a and C1b (307 and 317) can be connected in three ways: (1) between the audio input Vin and a reference voltage vcm if ϕ1a or ϕ1b are high; (2) between the inverting input and output of op amp 320 (the sample-and-hold op amp) if ϕ2a or ϕ2b are high; (3) between the inverting input and output of op amp 330 (the peak hold op amp) if ϕ3a or ϕ3b are high. On a given positive phase (let's call it phase a) of CKDCO (when ϕ1a or ϕ1b are high), the audio input is sampled onto EITHER capacitor C1a (307) OR capacitor C1b (317) (whose values are identical), depending on the state of ϕ3a. At the end of the input sample phase, when the audio input voltage has fully settled on the input capacitor C1a or C1b, the audio input voltage is compared to the peak hold output (as illustrated by the ϕ2 signal clocking comparator 340). During the negative phase of CKDCO (call it anti-phase a), the comparator 340 is given time to settle and the voltage sampled onto C1a or C1b is transferred to the sample-and-hold amplifier 320 via switch network 305/306 or 315/316. On the NEXT positive phase of CKDCO (phase b), the comparator result is utilized as follows: If the audio input sampled on the previous phase is larger than the current voltage on the peak output, the capacitor C1a or C1b whose voltage is being held by the sample-and-hold amplifier 320 is transferred to the peak hold amplifier 330 by opening switch pair 305/306 or 315/316 and closing switch pair 303/304 or 313/314, respectively. At the same time, the active sampling capacitor which is used to sample the audio input is swapped between C1a and C1b. In other words, if the peak hold amplifier voltage is held by C1a, capacitor C1b and switch network 311/312 will be used to sample the audio input on phase b.

In this way, it should be clear that if the input signal is rising continuously, the audio sampling will alternate between capacitors C1a and C1b on alternate cycles, with the peak signal constantly being updated by the currently sampled audio input. Conversely, if the audio input is smaller than the current peak signal, the capacitor holding the peak voltage (C1a or C1b) will remain in feedback around peak hold amplifier 330 and the input voltage will be sampled on the other capacitor (C1b or C1a) until such time as the input voltage will exceed the held peak voltage. The behavior of the clock phases ϕ1a/ϕ1b/ϕ2a/ϕ2b/ϕ3a/ϕ3b and operation of the peak detector will be more apparent when the details of the peak detector phase generator are shown and described below.

No peak detector would be complete without some kind of decay function to bleed the voltage level of the peak downward so that the peak detector can continue to detect peaks even when they are at equal or slightly lower amplitude than the previous peak. This is achieved in the current implementation by capacitor C2 (337) whose value is generally smaller than the values of C1a and C1b and a switch network consisting of four switches 331/332/333/334. Ordinarily switches 331 and 332 are closed (ϕ5 is high) and capacitor 337 is shorted out (both sides connected to reference voltage vcm). However, the CKDCO cycles are counted and every time a certain number of cycles elapse, the switches 331/332 open and switches 333/334 close, causing the peak voltage held by capacitor C1a or C1b to be attenuated by the charge sharing that takes place when the larger capacitor holding the peak voltage is shorted to a smaller capacitor discharged to zero volts. In the current implementation C2 is 55 times smaller than C1a/C1b; however, this value is arbitrary and almost any ratio of C2 to C1a/C1b should be considered to be within the scope of this disclosure.

It will be apparent to one skilled in the art that implementing the peak decay in this way, with a switched capacitor which is shorted across the peak detector output every time a certain number of CKDCO cycles elapse, creates a frequency-dependent decay time. This method determines a fundamental frequency of the input signal from the output of the dual switched-capacitor peak detectors, the sample period of the dual switched-capacitor peak detectors being proportional to a time period between a previous pair of voltage peaks detected in the input signal. In particular, when the FLL is locked, the peak decay over one audio cycle will be the same regardless of the audio frequency. This frequency-controlled decay time is the heart of the current disclosure and is exactly what enables it to function over an arbitrarily large range of input frequencies.

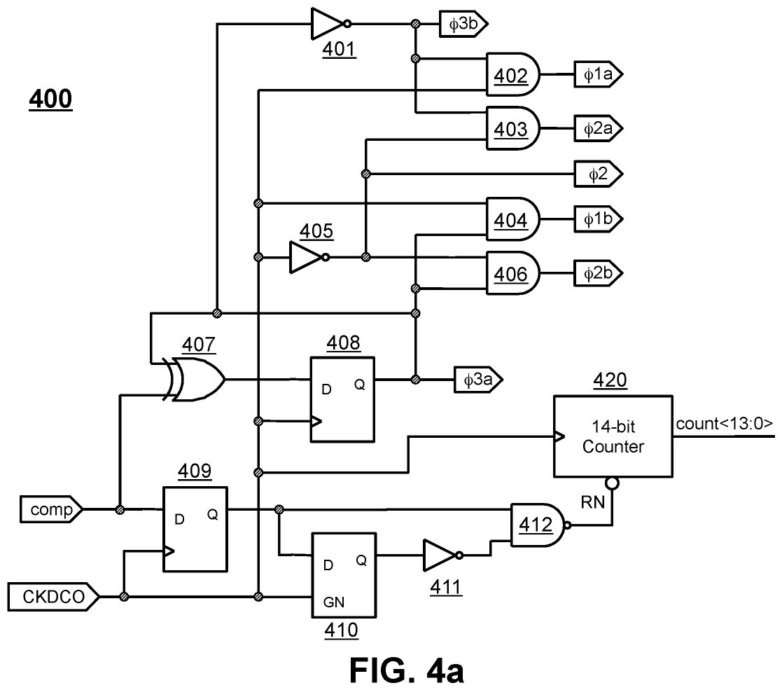

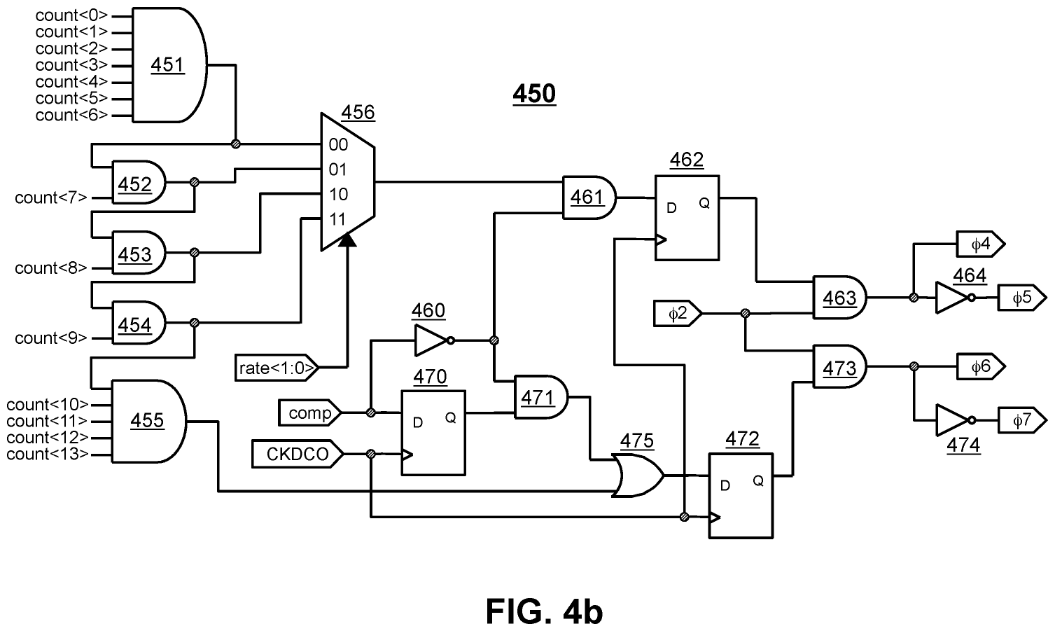

FIG. 4a and FIG. 4b are simplified schematics of the peak detector phase generator 350. Note that all phases are controlled by non-overlapping phase generators which insure that no two pair of switches are closed simultaneously, even for a very short period of time. Non-overlapping phase generators are well known in the art of switched capacitor circuits and aren't shown explicitly in the present disclosure, although it should be understood that they should be used to achieve the best possible performance. The peak detector phase generator operation can be understood as follows. The heart of the phase generator is XOR gate 407 and D flip-flop 408. The Q output of D flip-flop 408 serves as the ϕ3a phase, which is inverted via invertor 401 to generate ϕ3b. The output from comparator 340 “comp” is connected to one input of XOR gate 407 and the other input of this XOR gate is driven from the Q output of D flip-flop 408. The output of XOR gate 407 serves as the D input of flip-flop 408. In this way, if the comparator output “comp” is low, meaning that the audio input is smaller than the currently held peak value, D flip-flop 408 HOLDS its current state, meaning ϕ3a and ϕ3b remain as they are and the capacitor currently holding the peak value across peak hold op amp 330 remains connected there. Conversely, if the comparator output “comp” is high, meaning that the audio input is larger than the currently held peak value, the state held by D flip-flop 408 will change, causing the capacitor holding the current peak to be REPLACED by the capacitor holding the new (larger) peak.

The remaining pieces in FIG. 4a are simple enough to describe. AND gates 402 and 403 turn off phases ϕ1a and ϕ2a when ϕ3a is high and ϕ3b low (meaning C1b is sampling the audio input), and AND gates 404 and 406 turn off phases ϕ1b and ϕ2b when ϕ3b is high and ϕ3a low (meaning C1a is sampling the audio input). Inverter 405 inverts the CKDCO input to create the anti-phase clock signal ϕ2, whose positive edge clocks comparator 340. Additionally, there is a 14-bit counter 420, which generates a count<13:0> signal from which phases ϕ4 and ϕ5, which implement the frequency-dependent peak decay, are derived. The 14-bit counter 420 is reset every time a positive edge is detected on the “comp” input. The positive edge on “comp” is detected by latching the “comp” signal with D flip-flop 409 and then delaying the resulting signal by ½ of a CKDCO cycle with transparent latch 410 (with the clock input labeled “GN”). This transparent latch is transparent when the gate input “GN” is low and holds the value at the D input when the “GN” input goes high. The outputs of transparent latch 410 and D flip-flop 409 are combined with inverter 411 and NAND gate 412 to generate an active-low reset pulse for the 14-bit counter 420 which is ½ CKDCO cycle wide. This means the counter for generating the peak decay phases starts from zero every time an edge on the input signal is detected (that is, every time the comparator changes state from low to high).

FIG. 4b shows further details of the peak detector phase generator. In particular, the count<13:0> output of 14-bit counter 420 is used to generate periodic pulses on the ϕ4 output which short the peak decay capacitor C2 between the output and inverting input of peak hold op amp 330 which implement the frequency-dependent decay time. This is achieved as follows: There are four peak detector decay periods implemented in the current disclosure selected by a two-bit signal called rate<1:0>. If rate<1:0> is 00, the four-input MUX 456 in connection with 7-input AND gate 451 selects the pulse generated when count<0> through count<6> are all high. This occurs every 128 cycles of CKDCO, or 64 times per audio cycle (since there are 8,192 cycles of CKDCO in every audio cycle when the FLL is locked). If the “comp” signal is LOW, inverter 460 converts this to a high signal and AND gate 461 then allows this pulse to pass to the D input of D flip-flop 462. This pulse is delayed by one CKDCO cycle and then via AND gate 463 and inverter 464, creates a positive pulse on ϕ4 and negative pulse on ϕ5, connecting the peak decay capacitor C2 (337) in such a way to cause one step of decay in the held peak voltage. If the ratio of C2 to C1a/C1b is 55 as in the current disclosure, the new peak value will be 55/56 times the previous peak value. If the peak decay occurs 64 times in one cycle, as it will if the rate<1:0> signal is 00, the peak will decay to (55/56)⁶⁴=0.315 times its original value by the time the next peak occurs.

It will be apparent to one skilled in the art that utilizing peak detectors with decay time controlled by the frequency in this way to detect the fundamental frequency of a signal, makes this detection method immune to errors caused by zero crossings caused by higher harmonics in the signal, as long as the amplitude from those higher harmonics does not instantaneously exceed the decaying peak amount during one cycle. To account for signals with stronger harmonic content, the rate<1:0> input can be increased. FIG. 4b shows how increasing the rate to 01 causes 4-input MUX 456 to generate a positive pulse when count<7> is also high in addition to count<0> through count<6>; if rate<1:0> equals 10, count <8> must also be high in addition to count<0> thought count<7>; and if rate<1:0> equals 11, count <9> must also be high in addition to count<0> through count<8>. As a result, the peak decays every 64, 32, 16, or 8 cycles when the rate is 00, 01, 10, or 11, respectively.

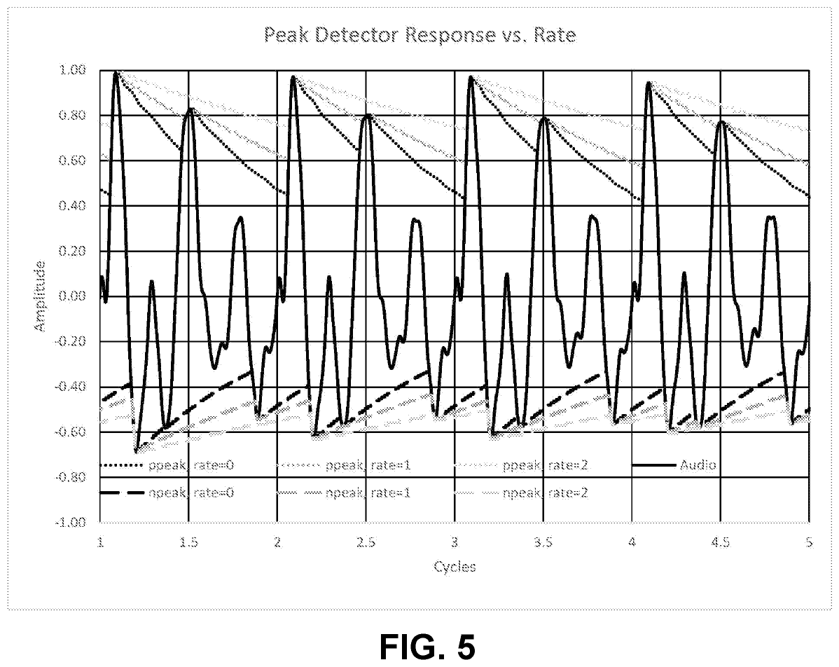

FIG. 5 illustrates graphically the behavior of the peak detector with frequency-dependent decay time for three different rates with a particularly difficult input signal, a violin playing the low G open string (196 Hz). Four cycles of the input waveform are shown; however, it is apparent from the audio signal that the harmonics cause waveform activity that can very easily fool the harmonic detection circuit into thinking the fundamental frequency is twice as high as it actually is. In particular, the mini-peaks at 1.5, 2.5, 3.5, and 4.5 cycles, if detected, will cause the FLL to lock to the second harmonic of this signal. Also shown are the positive and negative peaks ppeak and npeak for three different rates, 00, 01, and 10. It is apparent from the graphs that for rate=00 or 01, the second harmonic of the signal will be detected, whereas for rate=10 or higher, the true fundamental frequency will be detected. Note that it doesn't matter that multiple negative peaks are still detected between positive peaks for rate=10 and higher because the SR latch in FIG. 2 simply holds its state when multiple peaks of the same polarity are detected with no intervening peaks of the opposite polarity. The time period between the previous pair of detected voltage peaks is thus variable, so that the time period can be set long enough to avoid locking to a second or a higher harmonic depending on an instrument producing the input signal, but no longer than necessary to prevent cycle skipping when the audio signal decays.

It should be stated that there is a tradeoff between harmonic rejection and transient response using peak detectors with frequency-dependent decay time to detect the fundamental frequency of an audio signal. If the rate is set very high to reject very high harmonic energy, when the signal decays it is possible to MISS audio cycles as the signal can decay faster than the peak is decaying. For this reason, it is advisable to set the rate just high enough to avoid locking to the second (or a higher harmonic) depending on the instrument, but not higher than necessary to prevent cycle skipping when the audio signal decays. Bowed string instruments, for example, will require a higher rate setting and voices with lower harmonic content such as guitar and voice can generally function well with the rate set lower.

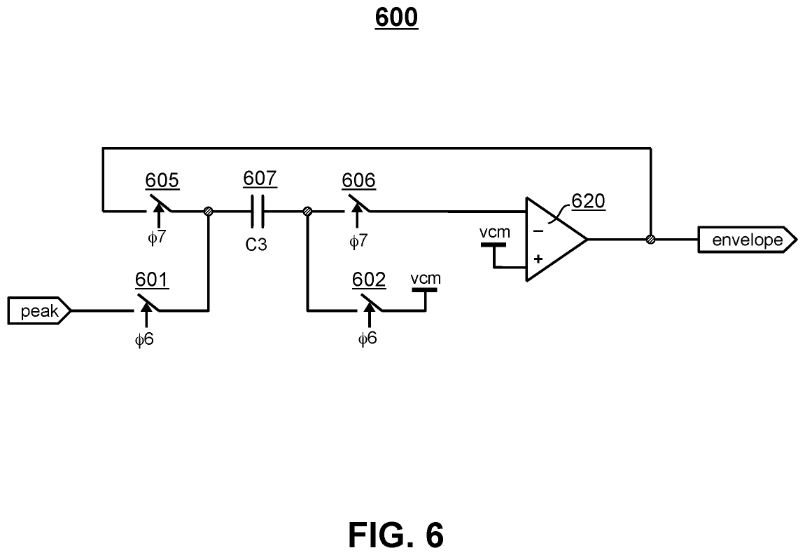

The rest of FIG. 4b and FIG. 6 illustrate an additional benefit that can be achieved with this disclosure for very little extra effort. Referring to FIG. 4b, D flip-flop 470, AND gate 471 and inverter 460 generate a positive pulse at the output of AND gate 471 whenever there is a negative edge detected on the “comp” input. This means the audio input is no longer higher than the peak hold signal and therefore the peak signal can be understood to represent the true “peak” of the audio signal over the past cycle. In connection with this, 5-input AND gate 455 generates a positive pulse whenever count<0> through count<13> are all high; in other words, every TWO audio cycles (since the 14-bit counter takes two audio cycles to come back to the all zeroes state). The output of AND gate 455 and the output of the negative “comp” edge detector from AND gate 471 are or'ed together with OR gate 475 and the result is used to generate an additional pair of clock phases, ϕ6 and ϕ7 using D flip-flip 472, AND gate 473 and inverter 474 in an analogous way to the generation of ϕ4 and ϕ5. These new phases ϕ6 and ϕ7 are used to clock a sample and hold amplifier that takes the peak hold signal as its input as shown in FIG. 6. FIG. 6 shows a standard switched capacitor sample-and-hold circuit which is not novel—the novelty in this disclosure is in how the phases for sample and hold are generated based on the state of the comparator 340 and 14-bit counter 420. The output of this sample-and-hold amplifier is labeled “envelope.” When peaks are detected, the maximum peak value is transferred to the “envelope” output whenever the “comp” signal transitions from high to low. Finally, to allow this envelope signal to decay, it samples the decaying peak signal every TWO audio cycles after peaks stop being detected. An additional switched-capacitor filter can be implemented to smooth out the envelope signal to avoid abrupt jumps in its value, but such filters are well known in the art and it is therefore not necessary to describe them in detail in this disclosure. The result of this final sample-and-hold circuit, plus optional switched-capacitor filtering which is not described herein, is a true ZERO RIPPLE envelope signal derived from an audio input, which is very useful for music synthesis applications. For example, if the detected envelope of an audio signal is used to control the amplitude of a sine wave, any ripple in the envelope is immediately audible as distortion in the sine wave. It is notoriously difficult to generate low ripple envelope signals, especially when the input frequency is very low. This zero ripple envelope detection technique can be used to avoid filtering of the envelope ripple, which also causes unwanted slowness in the transient behavior.

1. A method to detect a fundamental frequency of an input signal, the method comprising the steps of:
providing dual switched-capacitor voltage detectors connected to the input signal to periodically sample the voltage of the input signal, and then
determining a fundamental frequency of the input signal from the output of the dual switched-capacitor voltage detectors, the sample period of the dual switched-capacitor voltage detectors being proportional to a time period between a previous pair of voltage peaks detected in the input signal.

2. The method of claim 1 wherein the time period between the previous pair of detected voltage peaks is used to create a decay signal that initiates a capacitor decay time for each voltage detector.

3. The method of claim 2 wherein the time period is variable, so that the time period can be set long enough to avoid locking to a second or a higher harmonic depending on an instrument producing the input signal, but no longer than necessary to prevent cycle skipping when the audio signal decays.

4. The method of claim 3 wherein bowed string instruments require a longer time period and voices with lower harmonic content such as guitar and voice require a shorter time period.

5. The method of claim 1 wherein one of the dual switched-capacitor voltage detectors is driven by the input signal and the other of the dual switched-capacitor voltage detectors is driven by an inverted version of the input signal.

6. The method of claim 1 wherein each switched-capacitor voltage detector comprises at least one capacitor, six switches for each capacitor, two op amps, and another switched capacitor network containing a different capacitor and four switches, a comparator, and a digital phase generator circuit.

7. A frequency-locked loop circuit comprising: a digitally controlled oscillator configured to generate a first frequency; and a digital frequency iteration engine comprising: a first circuit configured to receive the first frequency and a reference frequency, and generate a number of first frequency cycles in one reference frequency cycle; and a second circuit configured to receive the number of first frequency cycles, and generate a second frequency based on a predetermined frequency multiplication factor, the determined number of first frequency cycles, the first frequency, and the reference frequency, wherein the predetermined frequency multiplication factor provides a target relationship between the first frequency and the reference frequency, and
dual switched-capacitor voltage detectors connected to an input signal to periodically sample the voltage of the input signal and to produce the reference frequency from the output of the dual switched-capacitor peak detectors, the sample rate of the dual switched-capacitor voltage detectors being proportional to the first frequency produced by the digitally controlled oscillator.

8. A method to detect a fundamental frequency of a signal, the method comprising the steps of:
providing a digitally controlled oscillator configured to generate a first frequency; and providing a digital frequency iteration engine comprising:
a first circuit configured to receive the first frequency and a reference frequency, and generate a number of first frequency cycles in one reference frequency cycle; and
providing a second circuit configured to receive the number of first frequency cycles, and generate a second frequency based on a predetermined frequency multiplication factor, the determined number of first frequency cycles, the first frequency, and the reference frequency, wherein the predetermined frequency multiplication factor provides a target relationship between the first frequency and the reference frequency, and
providing dual switched-capacitor voltage detectors connected to an input signal to periodically sample the voltage of the input signal and to produce the reference frequency from the output of the dual switched-capacitor peak detectors, the sample rate of the dual switched-capacitor voltage detectors being proportional to the first frequency produced by the digitally controlled oscillator.
